(19) United States
(12) Patent Application Publication
(10) Pub. No.: US 2009/0087961 A1
(43) Pub. Date: Apr. 2, 2009

(54) Process for fabricating semiconductor structures useful for the production of semiconductor-on-insulator substrates, and its applications

(76) Inventors: Jean-Michel HARTMANN, Le Versoud (FR); Laurent VANDROUX, Le Cheylas (FR)

Correspondence Address: BRINKS, HOFER, GILSON & LIONE, P.O. BOX 1340, MORRISVILLE, NC, 27560, US

(21) Appl. No.: 12/236,980

(22) Filed: Sep. 24, 2008

(30) Foreign Application Priority Data
Sep. 25, 2007 (FR) 07 57828

(51) Int. Cl. H01L 21/02

(52) U.S. Cl. 438/457; 438/763; 257/E21.002

(57) ABSTRACT

The invention relates to a process for fabricating a semiconductor structure, which comprises:
a step a) of providing an Si substrate having a front face and a rear face; and
a step b) that includes the epitaxial deposition, on the front face of the Si substrate, of a thick Ge layer, of an SiGe virtual substrate or of a multilayer comprising at least one thick Ge layer or at least one SiGe virtual substrate,

and which is characterized in that it further includes the deposition, on the rear face of the Si substrate, of a layer or a plurality of layers generating, on this rear face, flexural stresses that compensate for the flexural stresses that are exerted on the front face of said substrate after step b).

The invention also relates to a process for fabricating semiconductor-on-insulator substrates implementing the above process.

Applications in microelectronics and optoelectronics.

### TECHNICAL FIELD

The present invention relates to a process for fabricating semiconductor structures that consist of a multilayer comprising at least one silicon-germanium virtual substrate or at least one thick germanium layer on a silicon substrate, which structures are nevertheless free of any curvature.

Such semiconductor structures are useful as intermediate products, especially in the production of semiconductor-on-insulator substrates intended for use in microelectronics or in optoelectronics and comprising either a layer of strained silicon (sSOI or XsSOI) or a layer of strained germanium (sGeOI) or of unstrained germanium (GeOI), or else a layer of strained silicon-germanium (sSiGeOI) or of unstrained silicon-germanium (SiGeOI).

The present invention therefore also relates to a process for fabricating semiconductor-on-insulator substrates that implements this semiconductor structure fabrication process.

### DEFINITIONS

In the above and in what follows, the expression “silicon-germanium virtual substrate” is understood to mean a substrate formed by the multilayer consisting:
of a first layer, which is a silicon-germanium layer having an increasing germanium concentration gradient, it being possible for this gradient to range from 0 to 100% germanium, typically with a ramp of around 5 to 20% and, most often, 10% Ge per μm of thickness; and
a second layer, which is either a silicon-germanium layer of constant composition, and the germanium concentration of which is at least equal to the maximum germanium concentration of the first layer, or a pure germanium layer, this second layer generally having a thickness of around 1 to 2 μm and being virtually completely relaxed and relatively free of emergent dislocations (i.e. defects that pass through the thickness of the layer to emerge on the surface) which are harmful to the electron transport properties.

The conditions under which this type of multilayer is epitaxially grown on silicon substrates and their structural properties are well known to those skilled in the art. These have been described in particular by Y. Bogumilowicz et al. in Journal of Crystal Growth (274, 28-37, 2005 [1]; 283, 346-55, 2005 [2]; 290, 523-31, 2006 [3]) and in Solid State Phenomena (108-109, 445, 2005 [4]) and also by D. M. Isaacson et al. in Journal of Vacuum Science and Technology B 24, 2741-46, 2006 [5].

The expression “thick germanium layer” is understood to mean a layer of pure germanium with a thickness ranging from 0.1 to 10 μm and in particular from 0.2 to 6 μm, this layer typically being obtained by a process comprising the epitaxial growth of a germanium layer at low temperature (around 330 to 450° C.) followed by the growth of a germanium layer at high temperature (around 600 to 850° C.) supplemented, where appropriate, by a heat cycling treatment to reduce the density of emergent dislocations.

Here again, the conditions under which this type of layer is epitaxially grown on silicon substrates and their structural properties are well known to those skilled in the art who may, if necessary, refer to the articles published by J. M. Hartmann et al. in Journal of Crystal Growth 274, 90, 2005 [6], and by L. Clavelier et al. in ECS Transactions 3(7), 789, 2006 [7].

Moreover, a material (Si, Ge or SiGe) is considered to be “strained” when its crystallographic structure is strained tensilely or compressively during crystal growth, by epitaxy, requiring at least one lattice parameter to be different from the nominal lattice parameter of this material.

Conversely, a material is considered to be “unstrained” or “relaxed” when it has an unstrained crystallographic structure, i.e. one having a lattice parameter identical to the nominal lattice parameter of this material.

### PRIOR ART

Silicon-germanium virtual substrates and thick germanium layers as defined above are used as raw materials in the fabrication of semiconductor-on-insulator substrates of the SSOI, XsSOI, GeOI type or the like.

The epitaxial deposition of a silicon-germanium virtual substrate on a silicon substrate results in a curvature of the entire structure obtained, which curvature may either be slightly convex or be concave to a greater or lesser extent depending on the germanium concentration of the two layers forming this virtual substrate.

Similarly, after epitaxial deposition of a thick germanium layer on a silicon substrate, a concave curvature of the entire structure resulting from this deposition is observed.

To give an example, FIG. 1A shows, in the form of a curve, the size, expressed in μm, of the sags of the curvatures of structures consisting of a silicon-germanium virtual substrate formed by epitaxy directly on an Si(001) substrate as a function of the germanium concentration, expressed in %, of the constant composition layer located on top of this virtual substrate and, in the form of a cross, the size, again expressed in μm, of the sags of the curvatures of structures consisting of a thick germanium layer with a thickness of 2.3 μm, formed by epitaxy directly on an Si(001) substrate.

These curvatures are due to the fact that, in most industrial epitaxy equipment (such as chemical vapor deposition machines, reduced-pressure machines, etc.), the silicon wafers on which the silicon-germanium virtual substrates or the thick germanium layers are deposited rest flat on a support plate. Consequently, the layers grow only on that face of the silicon wafers exposed to the flux of gas or atoms, hence the existence of a strong asymmetry between the two faces of the wafers ultimately obtained.

Excessively large curvatures, such as those observed for example in the case of epitaxial deposition of silicon-germanium virtual substrates, the constant composition layer of which has a germanium concentration of 30% or more, make it difficult, or even impossible, to use such wafers for a subsequent bonding of layers to an oxidized silicon substrate, especially by the Smart Cut® process, with a view to obtaining semiconductor-on-insulator substrates of the sSOI, XsSOI, GeOI or sGeOI type or the like.

The inventors were therefore set the objective of providing a process for fabricating semiconductor structures which, although involving the epitaxial deposition of thick germanium layers or of silicon-germanium virtual substrates on silicon substrates, does nevertheless allow structures free of any curvature to be obtained.

The inventors were also set the objective of providing a process that is simple to implement, uses only techniques compatible with industrial production processes used in the microelectronics and optoelectronics field, and can be entirely carried out in an epitaxy machine.

The inventors were also set the objective of providing a process that does not cause metallic contamination of said thick germanium layers or of said silicon-germanium virtual substrates, such contamination being in fact incompatible with use of the structures in microelectronics.

### SUMMARY OF THE INVENTION

These objectives and yet others are achieved by the invention, which provides firstly a process for fabricating a semiconductor structure, which comprises:
a step a) of providing a silicon substrate S1 having a front face and a rear face; and
a step b) that includes at least the epitaxial deposition, on the front face of the substrate S1, of a thick germanium layer, of a silicon-germanium virtual substrate or of a multilayer comprising at least one thick germanium layer or at least one silicon-germanium virtual substrate,

and which is characterized in that it further includes the deposition, on the rear face of the substrate S1, of a layer or a plurality of layers generating, on this rear face, flexural stresses that compensate for the flexural stresses that are exerted on the front face of said substrate S1 after step b).

Thus, in accordance with the invention, the curvature induced by the epitaxial deposition, on the front face of a silicon substrate, of a thick germanium layer, of a silicon-germanium virtual substrate or of a multilayer comprising at least one such layer or one such virtual substrate is eliminated, or else the formation of such a curvature is prevented by depositing, on the rear face of this substrate, a layer or a set of layers that create, on this rear face, flexural stresses equivalent to those that are the cause of said curvature or which would be the cause if this rear-face deposition were not carried out.

According to a first advantageous arrangement of the invention, the flexural stresses exerted on the front face of the substrate S1 are compensated for by the epitaxial deposition of a thick germanium layer or by the deposition of a tensilely strained silicon nitride layer.

In this case, the thickness of the thick germanium layer or of the tensilely strained silicon nitride layer is preferably predetermined in such a way that depositing it on the rear face of the substrate S1 induces a curvature of the structure having a sag of the same size as the sag of the curvature induced by the flexural stresses exerted on the front face of the substrate S1 after step b) in the absence of any deposition on the rear face of said substrate S1.

According to another advantageous arrangement of the invention, the flexural stresses exerted on the front face of the substrate S1 are compensated for by the epitaxial deposition of several thick germanium layers or by the deposition of several tensilely strained silicon nitride layers, these layers preferably being two in number.

In this case, the thickness of the thick germanium layers or of the tensilely strained silicon nitride layers is predetermined so that their deposition on the rear face of the substrate S1 induces a curvature of the structure having a sag of the same size as the sag of the curvature induced by the flexural stresses that are exerted on the front face of the substrate S1 after step b) in the absence of any deposition on the rear face of said substrate S1.

According to yet another advantageous arrangement of the invention, the flexural stresses exerted on the front face of the substrate S1 are compensated for by the epitaxial deposition of one or more silicon-germanium virtual substrates or of a set of layers comprising one or more silicon-germanium virtual substrates.

This arrangement is particularly advantageous when step b) itself comprises the deposition, on the front face of the substrate S1, of one or more silicon-germanium virtual substrates or of a set of layers comprising one or more silicon-germanium virtual substrates.

In this case, the flexural stresses exerted on the front face of the substrate S1 are preferably compensated for by the epitaxial deposition of an architecture which is the “mirror” of that deposited on the front face of this substrate S1, i.e. an architecture which is identical, in terms of number, composition and thickness of its constituent layers, to that covering the front face of the substrate S1 and which is placed symmetrically to it with respect to said substrate S1.

In a first preferred method of implementing the process according to the invention:
step b) comprises the epitaxial deposition, on the front face of the substrate S1, of a silicon-germanium virtual substrate, the constant composition layer of which has a germanium concentration of 20 to 50% approximately; and
the flexural stresses exerted on the front face of the substrate S1 after step b) are compensated for either by the deposition of one or more tensilely strained silicon nitride layers or by the epitaxial deposition of one or more thick germanium layers or of a silicon-germanium virtual substrate identical to that deposited on the front face of the substrate S1 and placed symmetrically to it with respect to said substrate S1.

In a second preferred method of implementing the process according to the invention:
step b) comprises the epitaxial deposition, on the front face of the substrate S1, of a multilayer comprising, starting from this substrate and in the following order:
a silicon-germanium virtual substrate, the constant composition layer of which has a germanium concentration ranging from 20 to 50% approximately, and
a tensilely strained silicon (sSi) layer; and
   the flexural stresses exerted on the front face of the substrate S1 after step b) are compensated for either by the deposition of one or more tensilely strained silicon nitride layers or by the epitaxial deposition of one or more thick germanium layers or of a silicon-germanium virtual substrate identical to that deposited on the front face of the substrate S1 and placed symmetrically to it with respect to said substrate S1.

In a third preferred method of implementing the process according to the invention:
step b) comprises the epitaxial deposition, on the front face of the substrate S1, of a multilayer comprising, starting from this substrate and in the following order:
a first silicon-germanium virtual substrate, the constant composition layer of which has a germanium concentration of 50% approximately, and
a second silicon-germanium virtual substrate, the constant composition layer of which has a germanium concentration ranging from 60 to 100% approximately; and
   the flexural stresses exerted on the front face of the substrate S1 after step b) are compensated for either by the deposition of one or more tensilely strained silicon nitride layers or by the epitaxial deposition of one or more thick germanium layers or of a multilayer identical to that deposited on the front face of the substrate S1 and placed symmetrically to it with respect to said substrate S1.

In a fourth preferred method of implementing the process according to the invention:
step b) comprises the epitaxial deposition, on the front face of the substrate S1, of a multilayer comprising, starting from this substrate and in the following order:
a first silicon-germanium virtual substrate, the constant composition layer of which has a germanium concentration of 50% approximately,
a second silicon-germanium virtual substrate, the constant composition layer of which has a germanium concentration ranging from 60 to 100% approximately, and
an assembly formed from a tensilely strained silicon or silicon-germanium first layer, a compressively strained germanium second layer and a tensilely strained silicon third layer; and
   the flexural stresses exerted on the front face of the substrate S1 after step b) are compensated for either by the deposition of one or more tensilely strained silicon nitride layers or by the epitaxial deposition of one or more thick germanium layers or of a multilayer identical to that formed, on the front face of the substrate S1, by the two silicon-germanium virtual substrates deposited on this front face, and placed symmetrically to it with respect to said substrate S1.

In a fifth preferred method of implementing the process according to the invention:
step b) comprises the epitaxial deposition, on the front face of the substrate S1, of a multilayer comprising, starting from this substrate and in the following order:
a first silicon-germanium virtual substrate, the constant composition layer of which has a germanium concentration of 50% approximately,
a second silicon-germanium virtual substrate, the constant composition layer of which has a germanium concentration ranging from 60 to 100% approximately, and
an assembly formed from a tensilely strained silicon or silicon-germanium first layer, a compressively or tensilely strained silicon-germanium second layer and a tensilely strained silicon third layer; and
   the flexural stresses exerted on the front face of the substrate S1 after step b) are compensated for either by the deposition of one or more tensilely strained silicon nitride layers or by the epitaxial deposition of one or more thick germanium layers or of a multilayer identical to that formed, on the front face of the substrate S1, by the two silicon-germanium virtual substrates deposited on this front face, and placed symmetrically to it with respect to said substrate S1.

It should be noted that the deposition, on the rear face of the substrate S1, of the layer or layers intended to compensate for the flexural stresses exerted on the front face of this substrate may be carried out before, after or during step b) if the latter comprises several deposition operations, this being the case when step b) comprises the deposition of a multilayer on the front face of the substrate S1.

Moreover, when the flexural stresses exerted on the front face of the substrate S1 by the deposition of several thick germanium layers or several tensilely strained silicon nitride layers are compensated for, it is possible for these layers to be deposited both one after another and at various stages of the process according to the invention.

The subject of the invention is also a process for fabricating a semiconductor-on-insulator substrate, which comprises:
a step i) comprising the implementation of a process for fabricating a semiconductor structure as defined above; and
a step ii) comprising the bonding by molecular adhesion of part of this structure to a silicon substrate S2.

This process may in particular be used to fabricate a semiconductor-on-insulator substrate comprising an unstrained silicon-germanium layer with a germanium concentration of between 20 and 50%, in which case:
step i) comprises the implementation of a process for fabricating a semiconductor structure according to the first preferred method of implementation defined above, whereas
step ii) comprises the bonding by molecular adhesion, to the substrate S2, of part of the constant composition layer of the virtual substrate present on the front face of the substrate S1.

The bonding by molecular adhesion may in particular be carried out by the Smart Cut® process, in which case, when the substrate S2 is covered beforehand with a silicon oxide layer, step ii) preferably comprises:
the deposition of a silicon oxide layer on the constant composition layer of the virtual substrate;
an ion implantation into this layer in order to form a weakened zone therein;
the bonding by molecular adhesion of the silicon oxide layers covering the substrate S2 and the constant composition layer of the virtual substrate, respectively; and
the cleaving of the structure in the weakened zone, advantageously by heat treatment.

The process for fabricating a semiconductor-on-insulator substrate according to the invention may also be used to fabricate a substrate comprising a tensilely strained silicon layer, in which case:
step i) comprises the implementation of a process for fabricating a semiconductor structure according to the second preferred method of implementation defined above, whereas
step ii) comprises the bonding by molecular adhesion, to the substrate S2, of the tensilely strained silicon layer present on the front face of the substrate S1.

As previously, the bonding by molecular adhesion may in particular be carried out by the Smart Cut® process, in which case, when the substrate S2 is covered beforehand with a silicon oxide layer, step ii) preferably comprises:
the deposition of a silicon oxide layer on the tensilely strained silicon layer;
an ion implantation into the constant composition layer of the subjacent virtual substrate in order to form a weakened zone therein;
the bonding by molecular adhesion of the silicon oxide layers covering the substrate S2 and the tensilely strained silicon layer, respectively;
the cleaving of the structure in the weakened zone; and
the removal of the residual silicon-germanium layer covering the tensilely strained silicon layer.

It may also be used to fabricate a semiconductor-on-insulator substrate comprising an unstrained silicon-germanium layer with a germanium concentration equal to or greater than 60% or an unstrained pure germanium layer, in which case:
step i) comprises the implementation of a process for fabricating a semiconductor structure according to the third preferred method of implementation defined above, whereas
step ii) comprises the bonding by molecular adhesion, to the substrate S2, of part of the constant composition layer of the second virtual substrate present on the front face of the substrate S1.

Here again, the bonding by molecular adhesion may in particular be carried out by the Smart Cut® process, in which case, when the substrate S2 is covered beforehand with a silicon oxide layer, step ii) comprises:
the deposition of a silicon oxide layer on the constant composition layer of the second virtual substrate;
an ion implantation into this layer in order to form a weakened zone therein;
the bonding by molecular adhesion of the silicon oxide layers covering the substrate S2 and the constant composition layer of the second virtual substrate, respectively; and
the cleaving of the structure in the weakened zone.

It may also be used to fabricate a semiconductor-on-insulator substrate comprising a compressively strained germanium layer, in which case:
step i) comprises the implementation of a process for fabricating a semiconductor structure according to the fourth preferred method of implementation defined above, whereas
step ii) comprises the bonding by molecular adhesion, to the substrate S2, of the assembly formed by the tensilely strained silicon or silicon-germanium first layer, the compressively strained germanium second layer and the tensilely strained silicon third layer, present on the front face of the substrate S1.

Furthermore, it may be profitably used to fabricate a semiconductor-on-insulator substrate comprising a compressively or tensilely strained silicon-germanium layer, in which case:
step i) comprises the implementation of a process for fabricating a semiconductor structure according to the fifth preferred method of implementation defined above, whereas
step ii) comprises the bonding by molecular adhesion, to the substrate S2, of the assembly formed by the tensilely strained silicon or silicon-germanium first layer, the compressively or tensilely strained silicon-germanium second layer and the tensilely strained silicon third layer, on the front face of the substrate S1.

In these latter two cases, it is also possible to carry out the bonding by molecular adhesion by the Smart Cut® process, in which case, when the substrate S2 is covered beforehand with a silicon oxide layer, step ii) comprises:
the deposition of a silicon oxide layer on the tensilely strained silicon third layer;
an ion implantation into the constant composition layer of the subjacent second virtual substrate in order to form a weakened zone therein;
the bonding by molecular adhesion of the silicon oxide layers covering the substrate S2 and the tensilely strained silicon third layer, respectively;
the cleaving of the structure in the weakened zone; and
the removal of the residual silicon-germanium layer covering the tensilely strained silicon third layer.

In accordance with the invention, the substrates S1 and S2 are preferably chosen from Si(001) substrates, Si(100) substrates misoriented by 6° in one of the two <110> crystallographic directions, Si(110) substrates and Si(111) substrates.

Moreover, the substrate S1 is chosen from double-sided polished substrates when the strain-compensating layer or layers deposited on the rear face of this substrate are deposited epitaxially (which is the case with the thick germanium layers and with the silicon-germanium virtual substrates).

The invention will be better understood in the light of the rest of the following description, which refers to the appended figures.

Of course, the rest of this description is given merely to illustrate the subject matter of the invention and does not in any way constitute a limitation on this subject matter.

### BRIEF DESCRIPTION OF THE FIGURES

FIG. 1A shows, in the form of a curve, the size (in μm) of the sags of the curvatures of structures consisting of an SiGe virtual substrate formed by epitaxy directly on an Si(001) substrate as a function of the Ge concentration (in %) of the constant composition layer located on top of this virtual substrate and, in the form of a cross, the size (also in μm) of the sags of the curvatures of structures consisting of a thick Ge layer 2.3 μm in thickness formed by epitaxy directly on an Si(001) substrate.

FIG. 1B shows, in the form of a curve, the size (in μm) of the sags of the curvatures of structures consisting of a tensilely strained silicon nitride layer, formed by epitaxy directly on an Si(001) substrate, as a function of the thickness (in μm) of this layer.

FIG. 2 (parts A to K) illustrates schematically the various steps of a first method of implementing the process for fabricating a semiconductor-on-insulator substrate according to the invention, designed to fabricate an sGeOI substrate comprising a compressively strained germanium layer.

FIG. 3 (parts A to D) illustrates schematically the four first steps of a first variant of the first method of implementing the process for fabricating a semiconductor-on-insulator substrate according to the invention, the object of FIG. 2.

FIG. 4 (parts A to N) illustrates the various steps of a second variant of the first method of implementing the process for fabricating a semiconductor-on-insulator substrate according to the invention, the object of FIG. 2.

FIG. 5 (parts A to J) illustrates schematically the various steps of a second method of implementing the process for fabricating a semiconductor-on-insulator substrate according to the invention, designed to fabricate an XsSOI substrate.

FIG. 6 (parts A to E) illustrates schematically the first five steps of a variant of the second method of implementing the process for fabricating a semiconductor-on-insulator substrate according to the invention, the object of FIG. 5.

FIG. 7 (parts A to H) illustrates schematically the various steps of a third method of implementing the process for fabricating a semiconductor-on-insulator substrate according to the invention, designed to fabricate an SiGeOI substrate comprising an unstrained SiGe layer with a Ge concentration of 50% or less.

FIG. 8 (parts A to I) illustrates schematically the various steps of a fourth method of implementing the process for fabricating a semiconductor-on-insulator substrate according to the invention, designed to fabricate an SiGeOI substrate comprising an unstrained SiGe layer, with a concentration of greater than 50%, or a GeOI substrate comprising an unstrained pure Ge layer.

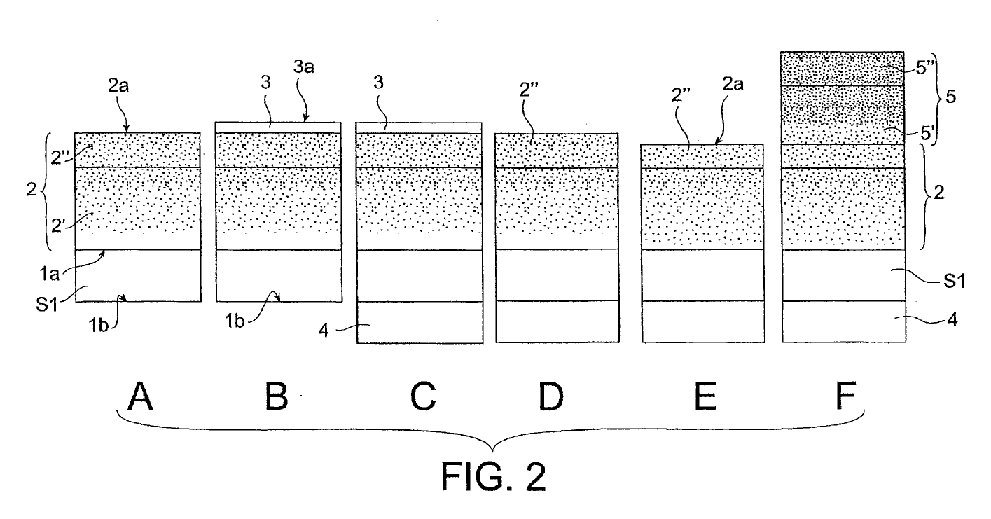

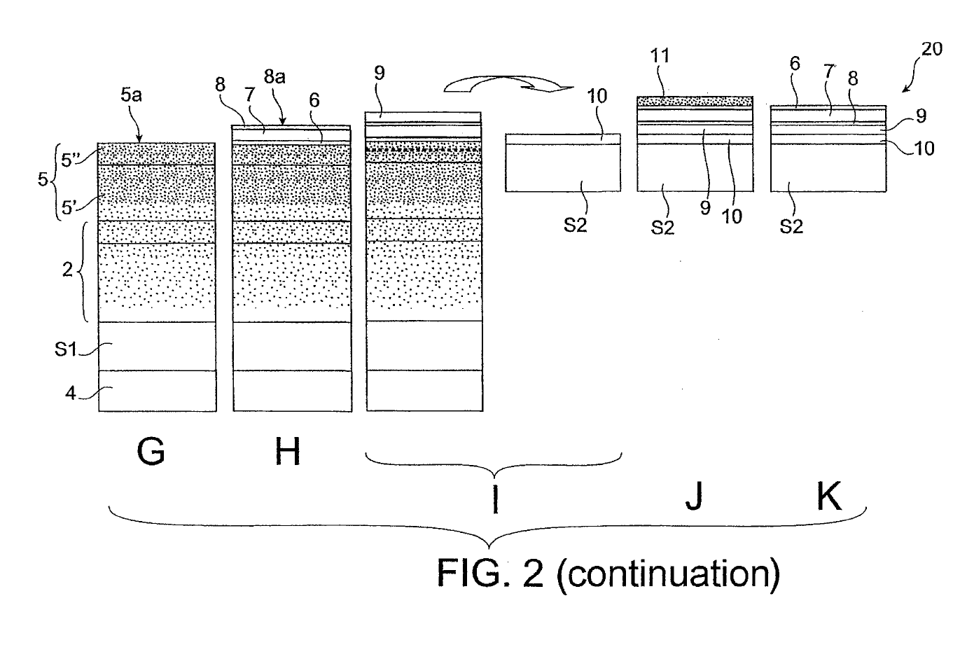

It should be noted that, for the sake of simplification, all the structures shown in FIGS. 2 to 8 have been depicted with plane surfaces even when they have a concave or convex curvature.

### DETAILED DESCRIPTION OF PARTICULAR EMBODIMENTS

The detailed description starts with FIG. 2 which schematically illustrates the various steps of a first method of implementing the process for fabricating a semiconductor-on-insulator substrate according to the invention, designed to fabricate an sGeOI substrate 20 having a compressively strained germanium layer 7, and in which process the flexural stresses generated on the front face of the silicon substrate on which this layer is initially formed are compensated for by the deposition of a thick Ge layer or a tensilely strained Si₃N₄ layer on the rear face of this substrate.

This method of implementation firstly comprises the epitaxial deposition of a first SiGe virtual substrate 2 on the front face 1a of a first Si substrate S1 (FIG. 2, part A).

The virtual substrate 2 comprises for example:
as first layer, an SiGe layer 2′ of which the germanium concentration gradient goes from a few % to 50%, with a ramp of around 10% Ge per μm of thickness; and
as second layer, an SiGe layer 2″ having 50% Ge, with a thickness of 1 to 2 μm.

As regards the substrate S1, this may for example be an Si(001) wafer, polished on one side or on both sides, that has been subjected beforehand to a final wet cleaning step using hydrofluoric acid, called “HF-last” (A. Abbadie et al., Applied Surface Science 225, 256-266, 2005 [8]).

The epitaxial deposition of the virtual substrate 2 on the front face 1a of the substrate S1 may be carried out, for example, by RP-CVD (Reduced-Pressure Chemical Vapor Deposition) under growth conditions similar to those described in the aforementioned reference [2].

The structure formed by the substrate S1 and the virtual substrate 2 has a concave curvature, i.e. the front face 2a of the layer 2 is concave while the rear face 1b of the substrate 1 is itself convex.

The virtual substrate 2 is then encapsulated with a protective layer 3 (FIG. 2, part B), for example an SiO₂ layer deposited conventionally, and then the structure is turned upside down and, after a cleaning step of the “HF-last” type carried out on the rear face 1b of the substrate S1, a strain-compensating layer 4 is deposited on this rear face, said layer 4 being:
either a thick Ge layer, in which case the substrate S1 must be polished on both its sides, and this layer is deposited by epitaxy, for example by RP-CVD using growth conditions similar to those described in the reference [6];
or a tensilely strained Si₃N₄ layer, in which case the substrate S1 may be polished only on its front face, and this layer is deposited, for example, by PE-CVD (Plasma-Enhanced Chemical Vapor Deposition), it being possible for the deposition parameters to be a temperature of around 480° C. and an SiH₄+NH₃+N₂ growth chemistry.

In all cases, the function of this layer is to compensate both for the flexural stresses already generated on the front face of the substrate S1 by the deposition of the virtual substrate 2 and those that will be generated on this same face, during the steps illustrated in FIG. 2, parts F and H, by the deposition of further layers, the objective being to obtain a plane structure, i.e. one free of any curvature, just before the direct wafer bonding illustrated in FIG. 2, parts I and J, is carried out.

The thickness of the layer 4 is therefore determined beforehand so that its deposition on the rear face of the substrate S1 results in an inversion of the curvature of the structure shown in FIG. 2, part B (the front face 3a of the layer 3 thus becoming convex and the rear face 1b of the substrate S1 thus becoming concave), which inversion must be all the more pronounced the higher the stresses intended to be generated on the front face of this substrate during the steps illustrated in FIG. 2, parts F and H.

To determine this thickness, the steps illustrated in FIG. 2, parts A to H, with the exception of the step consisting in depositing the layer 4 on the rear face of the substrate S1, are carried out beforehand on one or more Si substrates identical to the substrate S1, and the size of the sag of the curvature affecting the multilayer thus obtained is measured, for example by means of an apparatus of the FLEXUS F2320 type from KLA-TENCOR. Next, for example using a reference curve established beforehand by depositing layers of the same nature as the layer 4 that it is desired to deposit (i.e. a Ge layer or a tensilely strained Si₃N₄ layer depending on the case) but of variable thickness on Si substrates, which are also identical to the substrate S1, and by measuring the size of the sags of the curvatures thus obtained, the thickness that said layer 4 must have in order to induce a curvature having a sag the same size as that of this multilayer is determined.

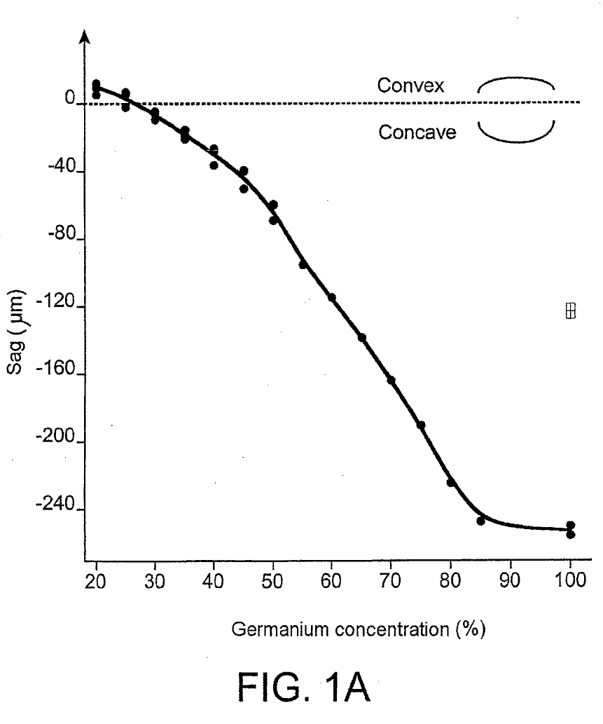

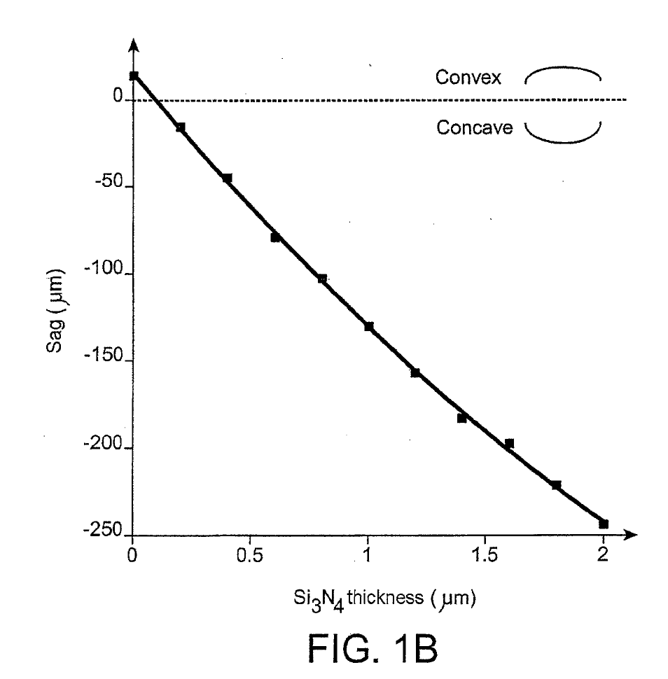

An example of a curve that can serve as a reference curve, having been established by depositing a tensilely strained Si₃N₄ layer of variable thickness on Si(001) substrates by PE-CVD (deposition temperature: 480° C.; growth chemistry: SiH₄+NH₃+N₂), is shown by way of illustration in FIG. 1B.

Once the layer 4 has been deposited, the structure is again inverted, and is then in accordance with that shown in FIG. 2, part C.

The protective layer 3 is removed (FIG. 2, part D), for example by dissolving it in hydrofluoric acid.

Next, the waviness affecting the free surface of the layer 2″ of the virtual substrate 2, which is inherent in this type of substrate, is eliminated by several CMP (Chemical-Mechanical Polishing) and associated cleaning operations carried out, for example, as described by Abbadie et al. in Microelectronic Engineering 83, 1986-1993, 2006 [9], this having the effect of substantially reducing the thickness of this layer, for example by around 0.5 μm (FIG. 2, part E).

Next, after HF-last cleaning of the front face 2a of the layer 2″ thus thinned, a second SiGe virtual substrate 5 is epitaxially deposited on this front face (FIG. 2, part F).

This second virtual substrate comprises for example:
as first layer, an SiGe layer 5′, the germanium concentration gradient of which ranges from 50% to a value between 60 and 90%, with a ramp of around 10% Ge per μm of thickness; and
as second layer, an SiGe layer 5″ having the same Ge concentration as the maximum Ge concentration of the layer 5′ and measuring from 1 to 2 μm in thickness.

The next step consists in eliminating the surface waviness of the layer 5″ of the virtual substrate 5 again, by several CMP and associated cleaning operations, which, again, has the effect of substantially reducing the thickness of this layer, for example by around 0.5 μm (FIG. 2, part G).

The front face 5a of the layer 5″ is then cleaned by HF-last cleaning and a multilayer instrain equilibrium, comprising a compressively strained Ge (cGe) layer 7 interspersed between two tensilely strained Si (sSi) layers 6 and 8 respectively (FIG. 2, part H), is deposited by epitaxy on this face.

The epitaxial deposition of this multilayer may be carried out for example by RP-CVD using growth conditions similar to those described by Y. Bogumilowicz et al. in Materials Science and Engineering B 124-125, 113, 2005 [10], given that the thicknesses of each of the layers 6, 7 and 8 that form this multilayer are to be adapted according to the Ge concentration of the layer 5″ of the subjacent virtual substrate 5. This is because the higher this Ge concentration, the smaller the thickness of the tensilely strained Si layers must be and the greater the thickness of the compressively strained Ge layer may be.

Thus, the maximum conceivable thicknesses are typically around 5 to 10 nm for the tensilely strained Si layers and 10 nm for the compressively strained Ge layer in the case of an Si_{0.4}Ge_{0.6} virtual substrate, whereas they are typically around 2 to 3 nm for the tensilely strained Si layers and a few tens of nm for the compressively strained Ge layer in the case of an Si_{0.1}Ge_{0.9} virtual substrate.

Next the sSi/cGe/sSi multilayer is transferred onto an Si(001) second substrate S2 covered beforehand with an SiO₂ layer 10, using the Smart Cut® process (FIG. 2, parts I and J), i.e. by:
deposition of an SiO₂ layer 9 on the front face 8a of the sSi layer 8;
ion implantation with an implantation peak in the core of the layer 5″ of the virtual substrate 5 in order to form a weakened zone therein (this zone being represented by dots in FIG. 2, part I);
bonding by molecular adhesion of the two SiO₂ layers 9 and 10;
heat treatment to consolidate the interface of the bonding by molecular adhesion and to cleave the layer 5″ of the virtual substrate 5 in the weakened zone; and
chemical-mechanical polishing of the residual SiGe layer 11 that covers the sSi/cGe/sSi multilayer thus transferred, in order to make the surface of this layer approximately smooth.

The residual SiGe layer 11 is then removed by etching with a suitable solution, for example an HF/H₂O₂/CH₃COOH (1/2/3 v/v) solution as described by Taraschi et al. in Journal of Vacuum Science and Technology B 20(2), 725-727, 2002 [11], or else using gaseous hydrochloric acid in the epitaxy machine, as described by Y. Bogumilowicz et al. in Semiconductor Science and Technology 20, 127-134, 2005 [12], the sSi layer 6 then serving as stop layer for this etching.

The sGeOI substrate 20 having a compressively strained germanium layer 7, shown in FIG. 2, part K, is thus obtained.

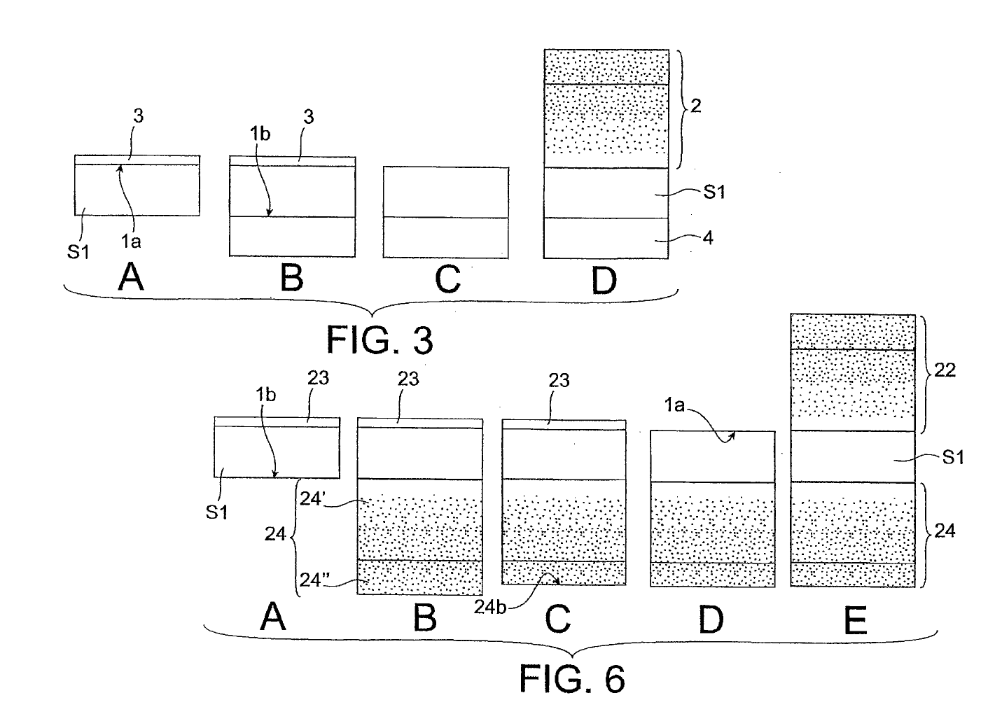

The description now refers to FIG. 3, which schematically illustrates the first four steps of a first variant of the first method of implementing the process for fabricating a semiconductor-on-insulator substrate described above, in which variant the flexural stresses generated on the front face of the substrate S1 during the production of the sGeOI substrate 20 are compensated for prior to the deposition of the first virtual substrate 2 and not thereafter.

Thus, in this variant, and as is visible in FIG. 3, part A, the process starts by depositing the protective layer 3 on the front face 1a of the substrate S1.

Next, after having inverted the structure thus obtained and subjected the rear face 1b of the substrate S1 to an HF-last cleaning operation, the layer 4 is deposited on this rear face, after which the structure is again inverted, which is then in accordance with that shown in FIG. 3, part B.

The protective layer 3 is then removed (FIG. 3, part C) and, after an HF-last cleaning operation carried out on the front face 1a of the substrate S1, the virtual substrate 2 is deposited on this front face (FIG. 3, part D).

Next, the same steps as those illustrated in FIG. 2, parts E to K are carried out.

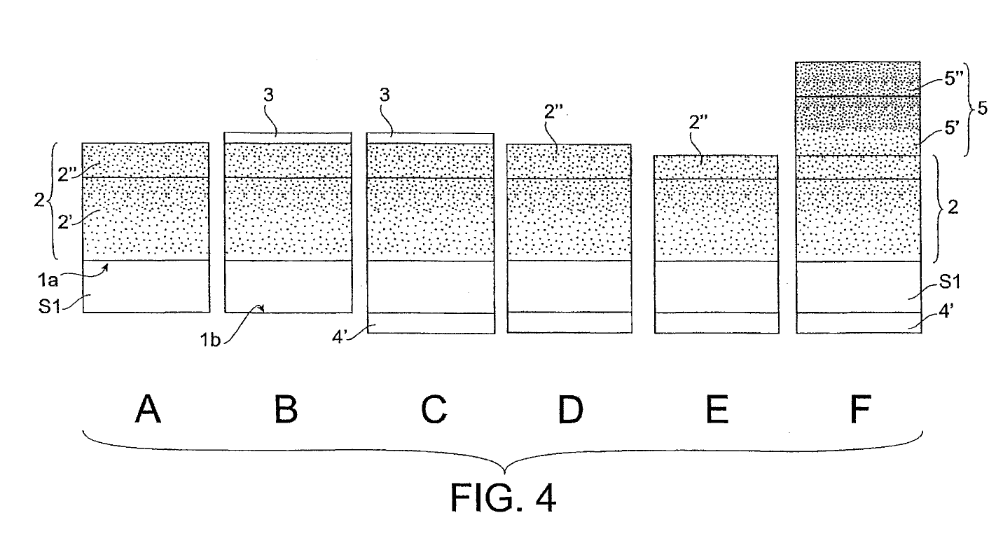

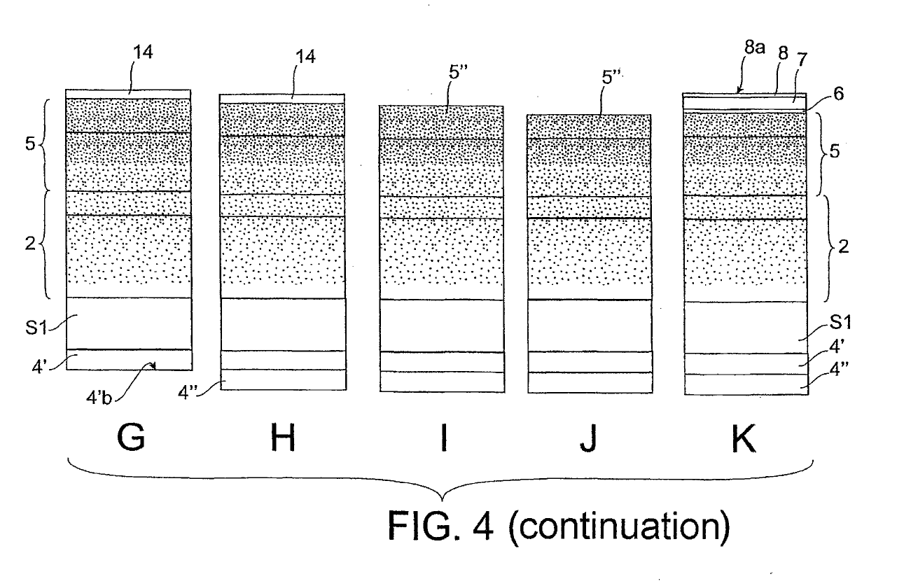

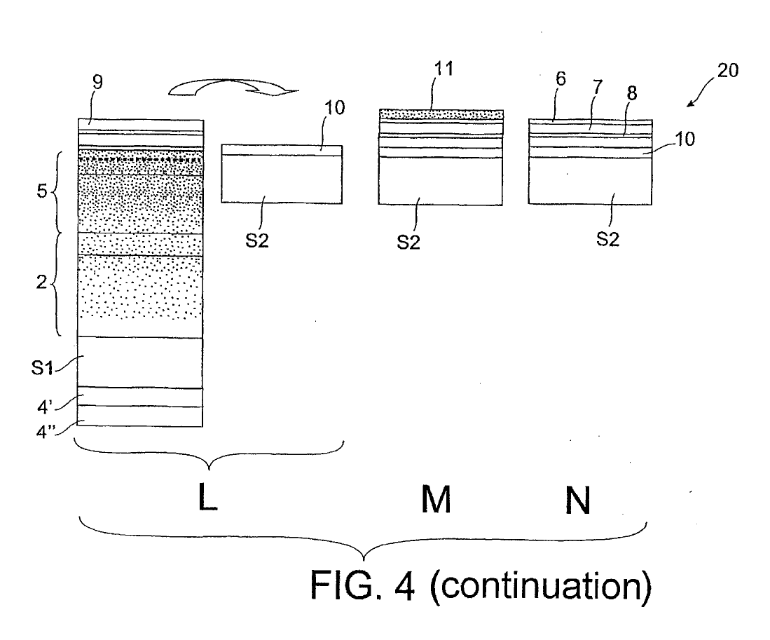

The description now refers to FIG. 4 which schematically illustrates the various steps of a second variant of the first method of implementing the process for fabricating a semiconductor-on-insulator substrate described above, in which variant the flexural stresses generated on the front face of the substrate 1 during the production of the sGeOI substrate 20 are compensated for in two steps.

This is because it may turn out that compensating for all the flexural stresses generated on the front face of the substrate S1 during the production of the sGeOI substrate 20 by the epitaxial deposition of a single thick Ge layer or a single tensilely strained Si₃N₄ layer, as described above, results in a structure curvature inversion that makes it difficult to carry out the subsequent steps, in particular for handling reasons in the equipment.

In this case, it is preferable to compensate for these stresses by epitaxially depositing two thick Ge layers or two tensilely strained Si₃N₄ layers, one after deposition of the first SiGe virtual substrate 2 and the other after deposition of the second SiGe virtual substrate 5.

Thus, after the first SiGe virtual substrate 2 has been epitaxially deposited on the front face 1a of the Si substrate S1 and this virtual substrate encapsulated with the protective layer 3 (FIG. 4, parts A and B) in the same way as described above, a first strain-compensating layer 4′ (FIG. 4, part C) is deposited on the rear face 1b of the substrate S1, the thickness of said layer 4′ being predetermined so that its deposition compensates only for the stresses generated by the deposition of the virtual substrate 2, or overcompensates for these stresses but without however overly inverting the concave curvature that the structure shown in FIG. 4, part B has.

After deposition of the first layer 4′, a plane structure or one with a very slightly convex curvature is therefore obtained.

Next, the protective layer 3 is removed (FIG. 4, part D), the surface waviness of the layer 2′ of the virtual substrate 2 is eliminated (FIG. 4, part E) by CMP and associated cleaning operations, and the virtual substrate 5 is epitaxially deposited (FIG. 4, part F) in the same way as described above, after which the structure thus obtained again has a concave curvature.

The virtual substrate 5 is then encapsulated with a protective layer 14 (FIG. 4, part G), for example an SiO₂ layer, and then a second strain-compensating layer 4″ (FIG. 4, part H) is deposited on the rear face 4′b of the first strain-compensating layer 4′, said second strain-compensating layer 4″ being of the same nature as that (Ge or tensilely strained Si₃N₄ depending on the case) and having a thickness corresponding to the difference between the thickness that a thick Ge layer or a tensilely strained Si₃N₄ layer would have, if this had been intended to compensate for all the flexural stresses generated on the front face of the substrate S1 during the production of the sGeOI substrate 20, and the thickness of the first layer 4′.

Once the second strain-compensating layer 4″ has been deposited, the protective layer 14 (part I of FIG. 4) is removed, for example by dissolving it in hydrofluoric acid, and then exactly the same steps as those illustrated in FIG. 2, parts G to K (FIG. 4, parts J to N) are carried out.

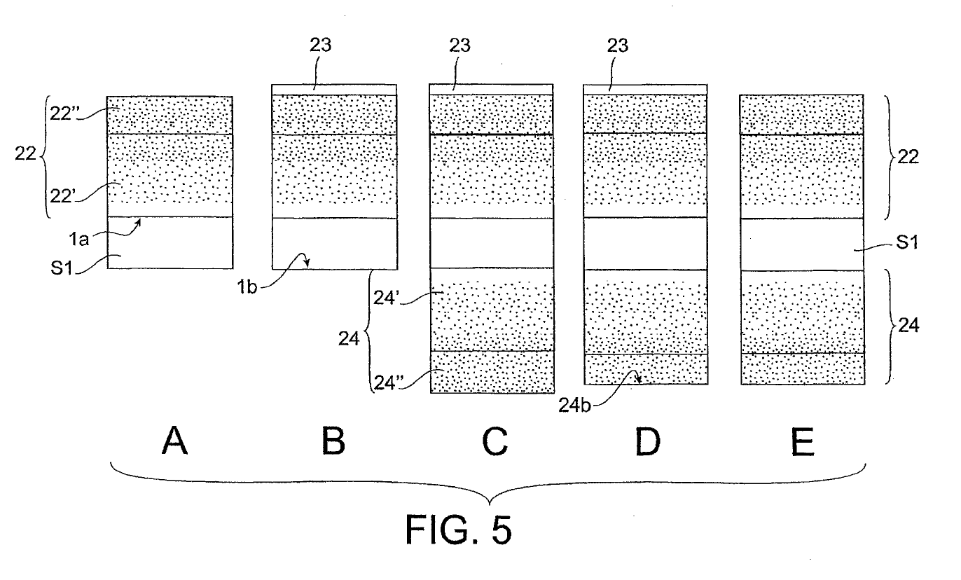

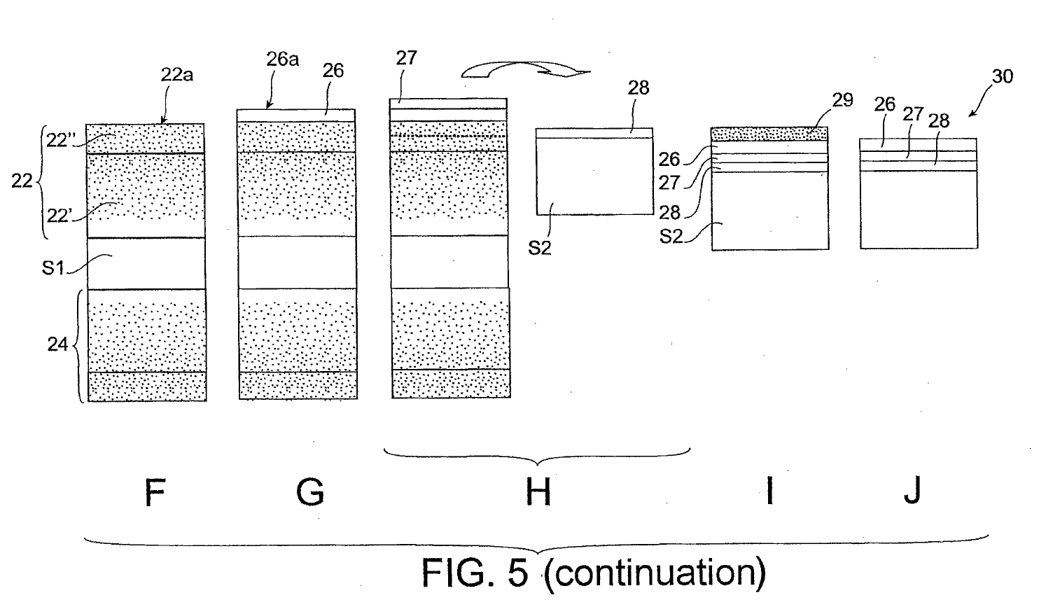

The description now refers to FIG. 5 which schematically illustrates the various steps of a second method of implementing the process for fabricating a semiconductor-on-insulator substrate according to the invention, designed to fabricate an XsSOI substrate 30, i.e. a substrate comprising a tensilely strained Si (sSi) layer 26 produced starting from an SiGe virtual substrate, the constant composition layer of which has a Ge concentration equal to or greater than 30% and in which the flexural stresses generated on the front face of the silicon substrate on which the layer 26 is initially formed are compensated for by the deposition of a mirror multilayer on the rear face of this substrate.

As in the previous method of implementation, the method starts with the epitaxial deposition of an SiGe virtual substrate 22 on the front face 1a of a first Si substrate S1 (FIG. 5, part A).

In this case, the virtual substrate 22 comprises:
as first layer, an SiGe layer 22′, the germanium concentration gradient of which varies from a few % to a value between 20 and 50%, with a ramp of around 10% Ge per μm of thickness; and
as second layer, an SiGe layer 22″ having the same Ge concentration as the maximum Ge concentration of the first layer 22′ and measuring from 1 to 2 μm in thickness,
   which is deposited, for example by RP-CVD, using growth conditions similar to those described in the aforementioned reference [2].

The substrate S1 is itself for example an Si(001) wafer, polished on both sides, which was subjected beforehand to a final cleaning of the HF-last type.

Next, the virtual substrate 22 is encapsulated with a protective layer 23 (FIG. 5, part B), for example an SiO₂ layer.

The structure is inverted and, after HF-last cleaning of the rear face 1b of the substrate S1, a multilayer which is the mirror of that intended to cover the front face 1a of the substrate S1 after the step illustrated in FIG. 5, part F, is formed on this rear face, the objective being, here again, to obtain a structure free of any curvature just before the direct wafer bonding illustrated in FIG. 5, parts H and I is carried out.

Now, the multilayer intended to cover the front face 1a of the substrate S1 after the step illustrated in FIG. 5, part F is made up of:
the layer 22′ of the virtual substrate 22; and
what will remain of the layer 22″ of this virtual substrate once its surface waviness has been eliminated, in the step shown in FIG. 5, part G, by CMP and associated cleaning operations, i.e. about 0.5 μm of the original layer 22″.

The mirror multilayer is therefore the multilayer obtained by:
epitaxially depositing, on the rear face 1b of the substrate S1, an SiGe virtual substrate 24 comprising layers 24′ and 24″ that are identical, respectively, as regards their composition and their thickness, to the layers 22′ and 22″ of the virtual substrate 22 (FIG. 5, part C); and then
eliminating the surface waviness of the layer 24″ of the virtual substrate 24 (FIG. 5, part D) under conditions identical to those intended to be used for eliminating the waviness of the layer 22″ of the virtual substrate 22.

Once the mirror multilayer has been deposited, the structure is again inverted and is then in accordance with that shown in FIG. 5, part D.

The protective layer 23 is removed (FIG. 5, part E), the surface waviness of the virtual substrate 22 (FIG. 5, part F) is eliminated and the sSi layer 26 is deposited (FIG. 5, part G).

This layer 26 may be deposited, for example, by RP-CVD using conditions similar to those described by J. M. Hartmann et al. in Semiconductor Science and Technology 22, 354-361, 2007 (13) and in Semiconductor Science and Technology 22, 362-368, 2007 [14].

Its thickness, which may range from 10 to 100 nm, is to be adapted according to the applications for which the XsSOI substrate 30 is intended and, most particularly, according to the Ge concentration of the layer 22″ of the subjacent virtual substrate 22. This is because the higher this concentration, the more desirable it is to reduce the thickness of the layer 26, as taught by the aforementioned references [13] and [14].

The sSi layer 26 is then transferred onto an Si(001) second substrate S2 covered beforehand with an SiO₂ layer 28, using the Smart Cut® process (FIG. 5, parts H and I), i.e. by:
deposition of an SiO₂ layer 27 on the front face 26a of the sSi layer 26;
ion implantation with an implantation peak in the core of the layer 22″ of the virtual substrate 22 in order to form therein a weakened zone (depicted by dots in FIG. 5, part H);
bonding by molecular adhesion of the two SiO₂ layers 27 and 28;
heat treatment to consolidate the interface of the bonding by molecular adhesion and to cleave the layer 22″ of the virtual substrate 22 in the weakened zone; and
chemical-mechanical polishing of the residual SiGe layer 29 that covers the sSi layer 26 in order to make the surface of this SiGe layer approximately smooth.

After the residual SiGe layer 29 has been removed, the XsSOI substrate 30 shown in FIG. 5, part J is obtained.

The description now refers to FIG. 6, parts A to E, which schematically illustrates the various steps of a variant of the second method of implementing the process for fabricating a semiconductor-on-insulator substrate that has just been described, in which variant the flexural stresses generated on the front face of the Si substrate S1 during the production of the XsSOI substrate 30 are compensated for prior to the deposition of the virtual substrate 22.

Thus, in this variant and as is visible in FIG. 6, part A, the method starts by the deposition of the protective layer 23 on the front face 1a of the substrate 1.

Next, the structure is inverted and, after HF-last cleaning of the rear face 1b of the substrate S1, the virtual substrate 24 is epitaxially deposited on this rear face (FIG. 6, part B) and the surface waviness of the layer 24″ of the virtual substrate 24 is eliminated (FIG. 6, part C) by CMP and associated cleaning operations.

The structure is again inverted and the protective layer 23 removed (FIG. 6, part D) and, after HF-last cleaning of the front face 1a of the substrate S1, the virtual substrate 22 is epitaxially deposited on this front face (FIG. 6, part E).

Next, the same steps as those illustrated in FIG. 5, parts F to J are carried out.

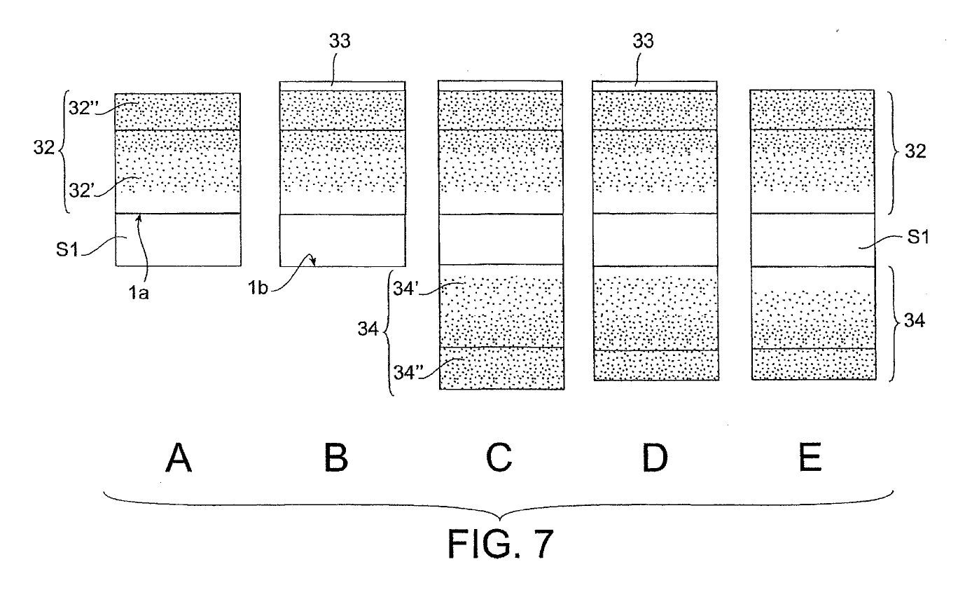

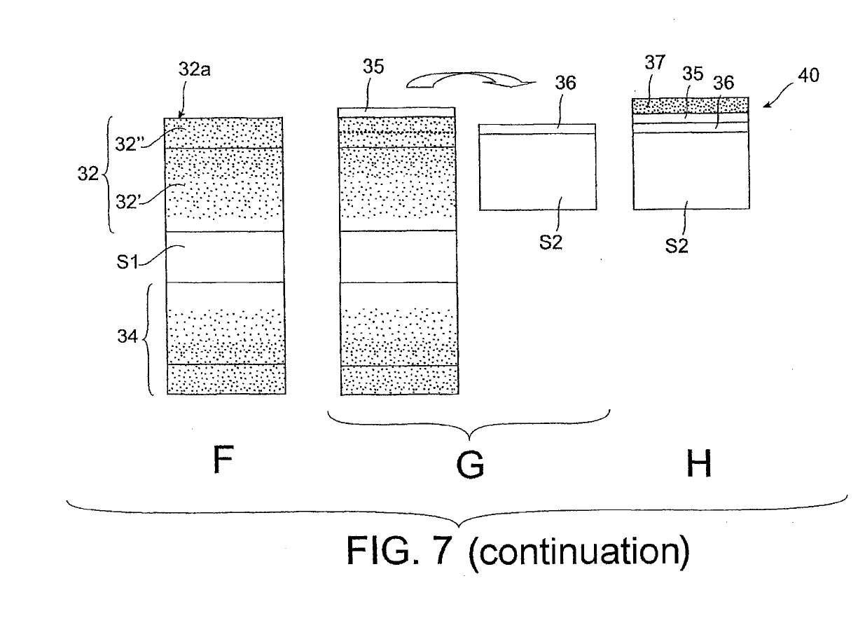

The description now refers to FIG. 7, parts A to H, which schematically illustrates the various steps of a third method of implementing the process for fabricating a semiconductor-on-insulator substrate according to the invention, designed to fabricate an SiGeOI substrate 40 comprising an unstrained SiGe layer 38, with a Ge concentration of 50% or less, and in which the flexural stresses generated on the front face of the silicon substrate on which this layer is initially formed are compensated for by the deposition of a mirror multilayer on the rear face of this substrate.

This method of implementation starts as illustrated in FIG. 5 by:
the epitaxial deposition, on the front face 1a of a first Si substrate S1, for example an Si(001) wafer, polished on both sides, of a first SiGe virtual substrate 32 comprising a first layer 32′ having a germanium concentration gradient ranging from a few % to 20-50%, with a ramp of around 10% Ge per μm of thickness, and a second SiGe layer 32″, with a thickness of 1 to 2 μm, having the same Ge concentration as the maximum Ge concentration of the first layer 32′ (FIG. 7, part A); then
the encapsulation of the virtual substrate 32 with a protective layer 33, for example an SiO₂ layer (FIG. 7, part B); and then
the formation, on the rear face 1b of the substrate S1, of a multilayer which is the mirror of that intended to cover the front face 1a of this substrate after the step illustrated in FIG. 7, part F, the objective being, here again, to obtain a plane structure just before the direct wafer bonding illustrated in FIG. 7, parts G and H is carried out.

However, in this case, the multilayer intended to cover the front face 1a of the substrate S1 after the step illustrated in FIG. 7, part F, is made up of:
the layer 32′ of the virtual substrate 32; and
what will remain of the layer 32″ of this virtual substrate once its surface waviness has been eliminated by CMP and associated cleaning operations, i.e. about 0.5 μm of the original layer 32″.

The mirror multilayer deposited on the rear face of the substrate S1 is therefore obtained by epitaxially depositing, on the rear face 1b of this substrate, an SiGe virtual substrate 34 comprising layers 34′ and 34″ that are identical both in their composition and in thickness to the layers 32′ and 32″, respectively, of the virtual substrate 32 (FIG. 7, part C) and then by eliminating the surface waviness of the layer 34″ of the virtual substrate 34 (FIG. 7, part D) under conditions identical to those intended to be used to eliminate the waviness of the layer 32″ of the virtual substrate 32.

Once the mirror multilayer has been deposited, the structure is again inverted and is then in accordance with that shown in FIG. 7, part D.

The protective layer 33 is removed (FIG. 7, part E) and the surface waviness of the layer 32″ of the virtual substrate 32 is eliminated (FIG. 7, part F) by CMP and associated cleaning operations.

Next, part of the layer 32″ of the virtual substrate 32 is transferred onto a second Si(001) substrate S2, covered beforehand with an SiO₂ layer 36, using the Smart Cut® process (FIG. 7, parts G and H), i.e. by:
deposition of an SiO₂ layer 35 on the front face 32a of the layer 32″ of the virtual substrate 32;
ion implantation with an implantation peak in the core of the layer 32″ of the virtual substrate 32 in order to constitute a weakened zone therein (depicted by dots in FIG. 7, part G);
bonding by molecular adhesion of the two SiO₂ layers 35 and 36;
heat treatment to consolidate the interface of the bonding by molecular adhesion and to cleave the layer 32″ of the virtual substrate 32 in the weakened zone; and then
mechanical-chemical polishing of the residual SiGe layer 38 that covers the SiO₂ layer 35 in order to smooth the surface of this SiGe layer.

Thus, the SiGeOI substrate 40 shown in FIG. 7, part H is obtained, which substrate comprises an unstrained SiGe layer 38 with a Ge concentration of around 20 to 50% and a thickness of a few tens of nm.

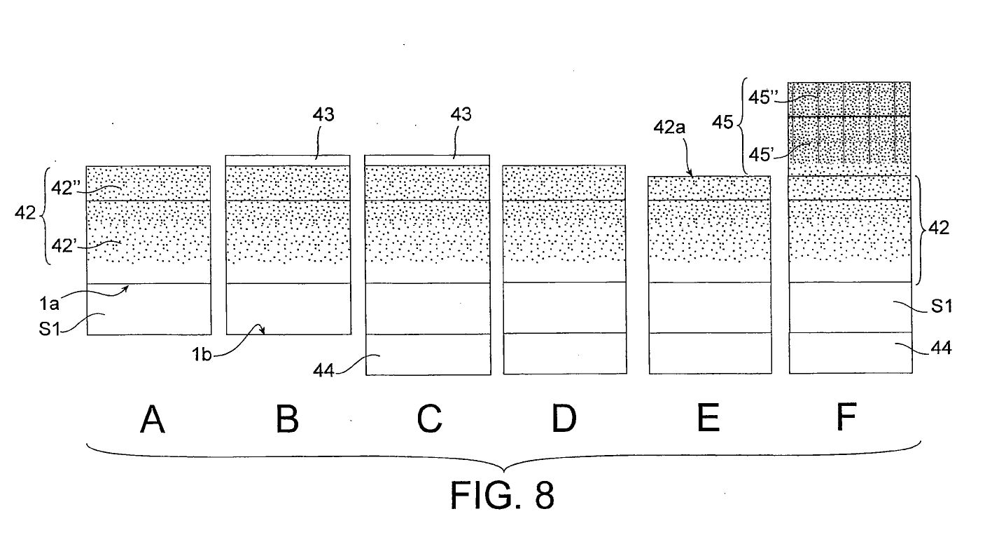

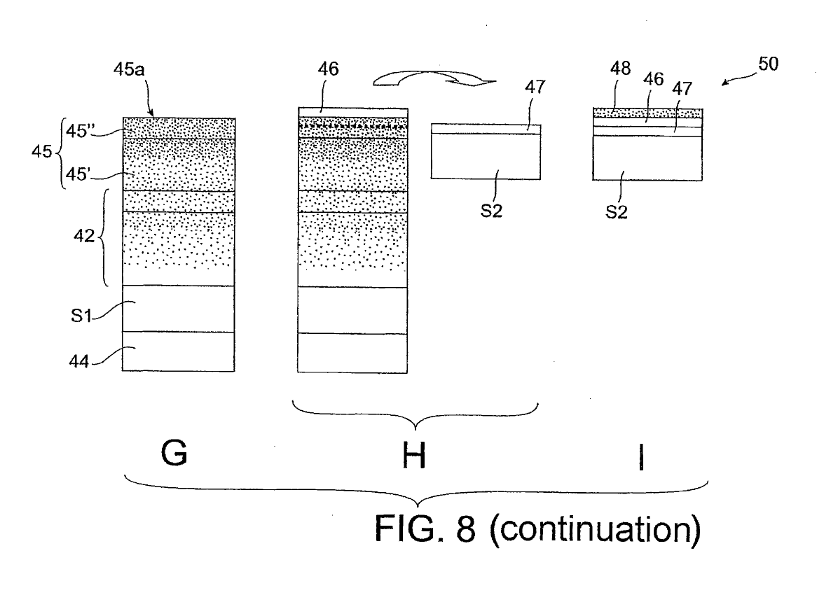

The description now refers to FIG. 8, which schematically illustrates the various steps of a fourth method of implementing the process for fabricating a semiconductor-on-insulator substrate according to the invention, designed to fabricate an SiGeOI substrate 50 having an unstrained SiGe layer 48 with a concentration greater than 50%, or else a GeOI substrate 50 having an unstrained pure Ge layer 48, and in which the flexural stresses generated on the front face of the silicon substrate on which the layer 48 is initially formed are compensated for by the deposition of a thick Ge layer or a tensilely strained Si₃N₄ layer on the rear face of this substrate.

This method of implementation comprises, as illustrated in FIG. 2:
the epitaxial deposition, on the front face 1a of a first Si substrate S1, for example an Si(001) wafer, polished on one side or on both sides, of a first SiGe virtual substrate 42 comprising a first layer 42′ having a germanium concentration gradient ranging from a few % to 50%, with a ramp of around 10% Ge per μm of thickness, and a second SiGe layer 42″ containing 50% Ge, with a thickness of 1 to 2 μm (FIG. 8, part A); then
the encapsulation of this virtual substrate with a protective layer 43, for example an SiO₂ layer (FIG. 8, part B); then
the deposition, on the rear face 1b of the substrate S1, of a strain-compensating layer 44 that may be a thick Ge layer formed by epitaxy or a tensilely strained Si₃N₄ layer (FIG. 8, part C); then
the removal of the protective layer 43 (FIG. 8, part D); then
the elimination of the surface waviness of the layer 42″ of the virtual substrate 42 (FIG. 8, part E) by CMP and associated cleaning operations; then
the epitaxial deposition, on the front face 42a of this virtual substrate, of a second SiGe virtual substrate 45, comprising a first layer 45′ having a germanium concentration gradient ranging from 50% to a value between 60 and 100%, with a ramp of around 10% Ge per μm of thickness, and a second SiGe layer 45″ from 1 to 2 μm in thickness, having the same Ge concentration as the maximum concentration of the layer 45′ (FIG. 8, part F); and then
the elimination of the surface waviness of the layer 45″ of the virtual substrate 45 (FIG. 8, part G).

However, in this method of implementation, the sSi/cGe/sSi multilayer is not deposited in strain equilibrium so that the flexural stresses generated on the front face of the substrate S1 are limited to the stresses generated by the deposition of the two virtual substrates 42 and 45.

As a consequence, the thickness of the layer 44 is therefore predetermined.

Next, part of the layer 45″ of the virtual substrate 45 is transferred onto a second Si(001) substrate S2, covered beforehand with an SiO₂ layer 47, using the Smart Cut® process (FIG. 8, parts H and I), i.e. by:
deposition of an SiO₂ layer 46 on the front face 45a of the layer 45″ of the virtual substrate 45;
ion implantation with an implantation peak in the core of the layer 45″ of the virtual substrate 45 in order to constitute a weakened zone therein (depicted by dots in FIG. 8, part H);
bonding by molecular adhesion of the two SiO₂ layers 46 and 47;
heat treatment to consolidate the interface of the bonding by molecular adhesion and to cleave the layer 45″ of the virtual substrate 45 in the weakened zone; and then
chemical-mechanical polishing of the residual SiGe or Ge layer 48 that covers the SiO₂ layer 46 in order to smooth the surface of this SiGe or Ge layer.

Thus, the SiGeOI or GeOI substrate 50 shown in FIG. 8, part I is obtained, which comprises a layer 48 either of unstrained SiGe, with a Ge concentration greater than 60%, or of unstrained pure Ge, the thickness of which is in both cases a few tens of nm.

The process according to the invention is in no way limited to the methods of implementation described above.

Thus, for example in the first method of implementation illustrated in FIG. 2 and its variants, it is quite conceivable to replace the compressively strained germanium layer 7 with an SiGe layer which is:
either compressively strained, in which case its Ge concentration is at least equal to the Ge concentration of the layer 5″ of the subjacent virtual substrate 5;
or tensilely strained, in which case its Ge concentration is less than the Ge concentration of the layer 5″ of the subjacent virtual substrate 5, for example making use of the operating points indicated by J. M. Hartmann in Journal of Crystal Growth 305, 113, 2007 [15]. Thus, the mobility of the charge carriers in said SiGe layer may be modulated.

It is also conceivable to replace the tensilely strained silicon layer 6 with a tensilely strained SiGe layer, with a Ge concentration less than that of the layer 5″ of the subjacent virtual substrate 5 so that this SiGe layer can, like said sSi layer 6, serve as etch stop layer.

Moreover, in all the embodiments that have just been described, the silicon (001) substrates may be replaced with other silicon substrates such as, for example, Si(100) substrates misoriented by 6° in one of the two <110> crystallographic directions, Si(110) substrates or Si(111) substrates.

Finally, it goes without saying that, in the methods of implementation illustrated in FIGS. 2, 3, 4 and 8, the flexural stresses generated on the front face of the substrates S1 may be compensated for by the epitaxial deposition, on the rear face of these substrates, of a multilayer which is the mirror of that intended to cover their front face after the steps illustrated in FIGS. 2H, 4K and 8G respectively.

Conversely, in the methods of implementation illustrated in FIGS. 5, 6 and 7, the flexural stresses generated on the front face of the substrates S1 may be compensated for by the deposition, on the rear face of these substrates, of one or more thick Ge layers by epitaxy or by one or more tensilely strained silicon nitride layers.

### REFERENCES CITED

[1] Y. Bogumilowicz et al., Journal of Crystal Growth 274, 28-37 (2005).
[2] Y. Bogumilowicz et al., Journal of Crystal Growth 283, 346-55 (2005).
[3] Y. Bogumilowicz et al., Journal of Crystal Growth 290, 523-31 (2006).
[4] Y. Bogumilowicz et al., Solid State Phenomena 108-109, 445 (2005).
[5] D. M. Isaacson et al., Journal of Vacuum Science and Technology B 24, 2741-46 (2006).
[6] J. M. Hartmann et al., Journal of Crystal Growth 274, 90 (2005).
[7] L. Clavelier et al., ECS Transactions 3(7), 789 (2006).
[8] A. Abbadie et al., Applied Surface Science 225, 256 (2004).
[9] A. Abbadie et al., Microelectronic Engineering 83, 1986-1993 (2006).
[10] Y. Bogumilowicz et al., Materials Science and Engineering B 124-125, 113 (2005).
[11] Taraschi et al., Journal of Vacuum Science and Technology B 20(2), 725-727 (2002).
[12] Y. Bogumilowicz et al., Semiconductor Science and Technology 20, 127-134 (2005).
[13] J. M. Hartmann et al., Semiconductor Science and Technology 22, 354-361 (2007).
[14] J. M. Hartmann et al., Semiconductor Science and Technology 22, 362-368 (2007).
[15] J. M. Hartmann, Journal of Crystal Growth 305, 113 (2007).

1. A process for fabricating a semiconductor structure comprising:
a) providing a silicon substrate having a front face and a rear face; and
b) epitaxially depositing, on the front face of the substrate, a thick germanium layer, of a silicon-germanium virtual substrate, or of a multilayer comprising at least one thick germanium layer, or at least one silicon-germanium virtual substrate,
the process further comprising depositing, on the rear face of the substrate, a layer or a plurality of layers generating flexural stresses on the rear face that compensate for flexural stresses that are exerted on the front face of substrate after step b).

2. The process according to claim 1, wherein the flexural stresses exerted on the front face of the substrate after step b) are compensated for by the epitaxial deposition of one or more thick germanium layers or of one or more tensilely strained silicon nitride layers.

3. The process according to claim 1, wherein the flexural stresses exerted on the front face of the substrate after step b) are compensated for by the epitaxial deposition of one or more silicon-germanium virtual substrates or of a set of layers comprising one or more silicon-germanium virtual substrates.

4. The process according to claim 3, wherein the flexural stresses exerted on the front face of the substrate after step b) are compensated for by the epitaxial deposition of an architecture which is the mirror of that deposited on the front face of said substrate.

5. The process according to claim 1, wherein step b) comprises the epitaxial deposition, on the front face of the substrate, of a silicon-germanium virtual substrate including a constant composition layer having a germanium concentration of approximately 20% to 50%; and
wherein the flexural stresses exerted on the front face of the substrate after step b) are compensated for either by the deposition of one or more tensilely strained silicon nitride layers, or by the epitaxial deposition of one or more thick germanium layers, or by a silicon-germanium virtual substrate identical to that deposited on the front face of the substrate and placed symmetrically to the front face with respect to the substrate.

6. The process according to claim 1, wherein
step b) further comprises the epitaxial deposition, on the front face of the substrate, of a multilayer comprising, starting from the substrate and in the following order:
a silicon-germanium virtual substrate including a constant composition layer having a germanium concentration ranging from approximately 20% to 50%, and
a tensilely strained silicon layer; and
the flexural stresses exerted on the front face of the substrate after step b) are compensated for either by the deposition of one or more tensilely strained silicon nitride layers, or by the epitaxial deposition of one or more thick germanium layers or of a silicon-germanium virtual substrate identical to that deposited on the front face of the substrate and placed symmetrically to the front face with respect to the substrate.

7. The process according to claim 1, wherein step b) comprises the epitaxial deposition, on the front face of the substrate, of a multilayer comprising, starting from the substrate and in the following order:
a first silicon-germanium virtual substrate, the constant composition layer of which has a germanium concentration of approximately 50%, and
a second silicon-germanium virtual substrate, the constant composition layer of which has a germanium concentration ranging from approximately 60% to 100%; and
the flexural stresses exerted on the front face of the substrate after step b) are compensated for either by the deposition of one or more tensilely strained silicon nitride layers, or by the epitaxial deposition of one or more thick germanium layers, or of a multilayer identical to that deposited on the front face of the substrate and placed symmetrically to the front face with respect to said substrate.

8. The process according to claim 1, wherein step b) comprises the epitaxial deposition, on the front face of the substrate, of a multilayer comprising, starting from the substrate and in the following order:
a first silicon-germanium virtual substrate including a constant composition layer having a germanium concentration of approximately 50%,
a second silicon-germanium virtual substrate including a constant composition layer having a germanium concentration ranging from approximately 60% to 100%, and
an assembly formed from a tensilely strained silicon or silicon-germanium first layer, a compressively strained germanium second layer and a tensilely strained silicon third layer; and
the flexural stresses exerted on the front face of the substrate after step b) are compensated for either by the deposition of one or more tensilely strained silicon nitride layers, or by the epitaxial deposition of one or more thick germanium layers, or by a multilayer identical to that formed on the front face of the substrate by the two silicon-germanium virtual substrates deposited on the front face and placed symmetrically to the front face with respect to the substrate.

9. The process according to claim 1, wherein: step b) comprises the epitaxial deposition, on the front face of the substrate, of a multilayer comprising, starting from substrate and in the following order:
a first silicon-germanium virtual substrate including a constant composition layer having a germanium concentration of approximately 50%,
a second silicon-germanium virtual substrate including a constant composition layer having a germanium concentration ranging from approximately 60% to 100%, and
an assembly formed from a tensilely strained silicon or silicon-germanium first layer, a compressively or tensilely strained silicon-germanium second layer, and a tensilely strained silicon third layer; and
the flexural stresses exerted on the front face of the substrate after step b) are compensated for either by the deposition of one or more tensilely strained silicon nitride layers, or by the epitaxial deposition of one or more thick germanium layers, or by a multilayer identical to that formed on the front face of the substrate, by the two silicon-germanium virtual substrates deposited on the front face and placed symmetrically to the front face with respect to the substrate.

10. A process for fabricating a semiconductor-on-insulator substrate, the process comprising:
implementing a process for fabricating a semiconductor structure as defined in claim 1; and
bonding a part of this structure by molecular adhesion to a second silicon substrate.

11. A process for fabricating a semiconductor-on-insulator substrate comprising an unstrained silicon-germanium layer with a germanium concentration of between approximately 20% and 50%, the process comprising:
a) providing a first silicon substrate having a front face and a rear face,
b) epitaxially depositing on the front face of the first substrate a silicon-germanium virtual substrate, including a constant composition layer having a germanium concentration of approximately 20% to 50%,
wherein flexural stresses exerted on the front face of the first substrate after step b) are compensated for either by the deposition of one or more tensilely strained silicon nitride layers, or by the epitaxial deposition of one or more thick germanium layers, or by a silicon-germanium virtual substrate identical to that deposited on the front face of the first substrate and placed symmetrically to the front face with respect to the first substrate; and
c) bonding a part of the constant composition layer of the virtual substrate by molecular adhesion to a second silicon substrate.

12. The process according to claim 11, wherein, when the second substrate is covered beforehand with a silicon oxide layer, bonding further comprises:
depositing a silicon oxide layer on the constant composition layer of the virtual substrate;
implanting ions into the silicon oxide layer in order to form a weakened zone therein;
bonding by molecular adhesion of the silicon oxide layers covering the second substrate and the constant composition layer of the virtual substrate, respectively; and
cleaving the structure in the weakened zone.

13. A process for fabricating a semiconductor-on-insulator substrate comprising a tensilely strained silicon layer, the process comprising:
a) providing a first silicon substrate having a front face and a rear face;
b) epitaxially depositing, on the front face of the first substrate, of a multilayer comprising, starting from the first substrate and in the following order:
a silicon-germanium virtual substrate including a constant composition layer having a germanium concentration ranging from approximately 20% to 50% and
a tensilely strained silicon layer, wherein the flexural stresses exerted on the front face of the first substrate after step b) are compensated for either by the deposition of one or more tensilely strained silicon nitride layers, or by the epitaxial deposition of one or more thick germanium layers, or by a silicon-germanium virtual substrate identical to that deposited on the front face of the first substrate and placed symmetrically to the front face with respect to the first substrate; and
c) bonding the tensilely strained silicon layer by molecular adhesion to a second silicon substrate.

14. The process according to claim 13, wherein, when the second substrate is covered beforehand with a silicon oxide layer, step c) further comprises:
depositing a silicon oxide layer on the tensilely strained silicon layer;
implanting ions into the constant composition layer of the subjacent virtual substrate in order to form a weakened zone therein;
bonding by molecular adhesion of the silicon oxide layers covering the second substrate and the tensilely strained silicon layer, respectively;
cleaving the structure in the weakened zone; and
removing the residual silicon-germanium layer covering the tensilely strained silicon layer.

15. A process for fabricating a semiconductor-on-insulator substrate comprising an unstrained silicon-germanium layer with a germanium concentration equal to or greater than 60%, or an unstrained pure germanium layer, the process comprising:
a) providing a first silicon substrate having a front face and a rear face,
b) epitaxially depositing on the front face of the first substrate, of a multilayer comprising, starting from the first substrate and in the following order:
a first silicon-germanium virtual substrate including a constant composition layer having a germanium concentration of approximately 50%, and
a second silicon-germanium virtual substrate, including a constant composition layer having a germanium concentration ranging from approximately 60% to 100%,
wherein the flexural stresses exerted on the front face of the first substrate after step b) are compensated for either by the deposition of one or more tensilely strained silicon nitride layers, or by the epitaxial deposition of one or more thick germanium layers, or by a multilayer identical to that deposited on the front face of the first substrate and placed symmetrically to the front face with respect to the first substrate; and
c) bonding a part of the constant composition layer by molecular adhesion to a silicon second substrate.

16. The process according to claim 15, wherein the second substrate is covered beforehand with a silicon oxide layer, step c) further comprises:
depositing a silicon oxide layer on the constant composition layer of the second virtual substrate;
implanting ions into this layer in order to form a weakened zone therein;
bonding by molecular adhesion of the silicon oxide layers covering the second substrate and the constant composition layer of the second virtual substrate, respectively; and
cleaving the structure in the weakened zone.

17. A process for fabricating a semiconductor-on-insulator substrate comprising a compressively strained germanium layer, the process comprising:
a) providing a first silicon substrate having a front face and a rear face,
b) epitaxially depositing on the front face of the first substrate, a multilayer comprising, starting from the first substrate and in the following order:
a first silicon-germanium virtual substrate, including a constant composition layer having a germanium concentration of approximately 50%,
a second silicon-germanium virtual substrate, including a constant composition layer having a germanium concentration ranging from approximately 60% to 100%, and
an assembly formed from a tensilely strained silicon or silicon-germanium first layer, a compressively strained germanium second layer, and a tensilely strained silicon third layer,
wherein the flexural stresses exerted on the front face of the first substrate after step b) are compensated for either by the deposition of one or more tensilely strained silicon nitride layers, or by the epitaxial deposition of one or more thick germanium layers, or by a multilayer identical to that formed, on the front face of the first substrate, by the two silicon-germanium virtual substrates deposited on the front face, and placed symmetrically to the front with respect to the first substrate; and
c) bonding the assembly by molecular adhesion to a second silicon substrate.

18. A process for fabricating a semiconductor-on-insulator substrate comprising a compressively or tensilely strained silicon-germanium layer, the process comprising:
a) providing a first silicon substrate having a front face and a rear face,
b) epitaxially depositing, on the front face of the first silicon substrate, of a multilayer comprising, starting from the first substrate and in the following order:
a first silicon-germanium virtual substrate, including a constant composition layer having a germanium concentration of approximately 50%,
a second silicon-germanium virtual substrate, including a constant composition layer having a germanium concentration ranging from approximately 60% to 100%, and
an assembly formed from a tensilely strained silicon or silicon-germanium first layer, a compressively or tensilely strained silicon-germanium second layer, and a tensilely strained silicon third layer,
wherein the flexural stresses exerted on the front face of the first silicon substrate after step b) are compensated for either by the deposition of one or more tensilely strained silicon nitride layers, or by the epitaxial deposition of one or more thick germanium layers, or by a multilayer identical to that formed on the front face of the first silicon substrate by the two silicon-germanium virtual substrates deposited on the front face and placed symmetrically to the front with respect to the first silicon substrate; and
c) bonding, the assembly to a second silicon substrate by molecular adhesion.

19. The process according to claim 18, wherein, when the second substrate is covered beforehand with a silicon oxide layer, step c) further comprises:
depositing a silicon oxide layer on the tensilely strained silicon third layer;
implanting ions into the constant composition layer of the subjacent second virtual substrate in order to form a weakened zone therein;
bonding by molecular adhesion of the silicon oxide layers covering the second substrate and the tensilely strained silicon third layer, respectively;
cleaving the structure in the weakened zone; and
removing the residual silicon-germanium layer covering the tensilely strained silicon third layer.

20. The process according to claim 10, wherein the first and second substrates comprise one or more of Si (001) substrates, Si (100) substrates misoriented by 6° in one of the two <110> crystallographic directions, Si (110) substrates, and Si (111) substrates.

21. The process according to claim 11, wherein the first and second substrates comprise one or more of Si (001) substrates, Si (100) substrates misoriented by 60° in one of the two <110> crystallographic directions, Si (110) substrates, and Si (111) substrates.

22. The process according to claim 13, wherein the first and second substrates comprise one or more of Si (001) substrates, Si (100) substrates misoriented by 60° in one of the two <110> crystallographic directions, Si (110) substrates, and Si (111) substrates.

23. The process according to claim 15, wherein the first and second substrates comprise one or more of Si (001) substrates, Si (100) substrates misoriented by 6° in one of the two <110> crystallographic directions, Si (110) substrates, and Si (111) substrates.

24. The process according to claim 17, wherein the first and second substrates comprise one or more of Si (001) substrates, Si (100) substrates misoriented by 60° in one of the two <110> crystallographic directions, Si (110) substrates, and Si (111) substrates.

25. The process according to claim 18, wherein the first and second substrates comprise one or more of Si (001) substrates, Si (100) substrates misoriented by 60° in one of the two <110> crystallographic directions, Si (110) substrates, and Si (111) substrates.
